(19) United States
(12) Patent Application Publication
(10) Pub. No.: US 2017/0287722 A1
(43) Pub. Date: Oct. 5, 2017

(54) MANUFACTURING METHOD OF SEMICONDUCTOR DEVICE AND MAINTENANCE METHOD OF DRY ETCHING EQUIPMENT

(71) Applicant: Renesas Electronics Corporation, Tokyo (JP)

(72) Inventor: Toshikazu HANAWA, Ibaraki (JP)

(21) Appl. No.: 15/430,457

(22) Filed: Feb. 11, 2017

(30) Foreign Application Priority Data
Mar. 31, 2016 (JP) 2016-069974

(51) Int. Cl. H01L 21/3065; H01L 23/34

(52) U.S. Cl. CPC H01L 21/3065; H01L 23/34

(57) ABSTRACT

The manufacturing yield of a semiconductor product is attempted to improve by reducing a particle and stabilizing an etching characteristic after the maintenance of a processing chamber in a dry etching equipment.

The temperature in a processing chamber is raised to a temperature not lower than an actual process temperature after the maintenance of the processing chamber before the vacuation of the processing chamber, residual moisture adsorbing in the processing chamber is removed sufficiently, and successively the processing chamber is vacuated.

### CLAIM OF PRIORITY

The present application claims priority from Japanese Patent application serial no. 2016-069974, filed on Mar. 31, 2016, the content of which is hereby incorporated by reference into this application.

### BACKGROUND OF THE INVENTION

### Field of the Invention

The present invention relates: to a manufacturing method of a semiconductor device; in particular to a maintenance method of a dry etching equipment used in a dry etching process.

### Description of the Related Art

In a dry etching equipment used in a semiconductor manufacturing process, a semiconductor wafer the surface of which is coated with a film to be etched, such as a silicon oxide film (SiO₂ film) or an aluminum film (Al film), is carried in a processing chamber, successively an etching gas is introduced, plasma is generated in the etching gas by applying high frequency waves or microwaves, and the film to be etched is processed by the chemical reaction with a radical and accelerated ions.

When dry etching is repeated, a reaction product generated by the etching deposits over the inner wall of a processing chamber or the surface of a part in the processing chamber as a polymer and acts as a dust source or causes abnormal electric discharge, and hence maintenance of opening the processing chamber to the atmosphere periodically and removing the reaction product attaching to the inner wall of the processing chamber or the part in the interior is required.

When the processing chamber is opened to the atmosphere and the maintenance is applied, the attaching state of the deposit and the atmosphere in the processing chamber vary between before and after the maintenance and hence an etching characteristic and the number of particles are not stabilized sometimes unless a certain period of electric discharge time lapses.

As a background technology in this technological field, there is a technology described in Patent Literature 1, for example. Patent Literature 1 discloses a method of stabilizing a characteristic by attaching an intentionally selected reaction product to the inner wall of a processing chamber after the maintenance of the processing chamber.

Further, Patent Literature 2 discloses a method of preprocessing a dry etching equipment by cleaning the etching equipment, successively assembling the etching equipment, adding a deposition-type gas during preliminary electric discharge after vacuation and baking, thus removing moisture in the etching equipment system, and thus starting up the cleaned etching equipment quickly.

Furthermore, Patent Literature 3 discloses a parallel plate type dry etching equipment to restrain a reaction product from attaching to an upper electrode (second electrode) by installing a heater to heat a surface in the interior or the vicinity of the upper electrode (second electrode).

### CITATION LIST

### Patent Literature

[Patent Literature 1] Japanese Patent Application Laid-Open No. 2008-244292

[Patent Literature 2] Japanese Patent Application Laid-Open No. H5 (1993)-190516

[Patent Literature 3] Japanese Patent Application Laid-Open No. H5 (1993)-306478

Although various efforts to cope with the variation of an etching characteristic and the generation of a particle before and after the maintenance of a dry etching equipment have been made as stated above, the grounds and mechanisms are not sufficiently clarified and the effects of the existing technologies such as the preliminary electric discharge (preconditioning electric discharge) as disclosed in Patent Literature 1 and 2 and the reaction product attachment prevention by a heater as disclosed in Patent Literature 3 are limited.

The other problems and novel features will be obvious from the descriptions and attached drawings in the present specification.

### SUMMARY OF THE INVENTION

According to one embodiment, temperature in a processing chamber is raised to a temperature not lower than an actual process temperature after the maintenance of the processing chamber before vacuation, thus residual moisture adsorbing to the processing chamber is removed sufficiently, and successively the processing chamber is vacuated.

According to the one embodiment, it is possible to reduce the quantity of residual moisture in a processing chamber effectively and restrain the influence of the moisture during processing.

As a result, it is possible to: restrain an excessive deposition component in the processing chamber; and attempt to reduce a particle and stabilize an etching characteristic (pattern shift) in a dry etching equipment.

### BRIEF DESCRIPTION OF THE DRAWINGS

FIG. 1 is a view illustrating the outline of a dry etching equipment according to one embodiment of the present invention;

FIG. 2 is a view illustrating the outline of a control system of a dry etching equipment according to one embodiment of the present invention;

FIG. 3 is a flowchart illustrating a maintenance method according to one embodiment of the present invention;

FIG. 4 is a graph representing time-series transition of the number of particles;

FIG. 5 is a view illustrating the outline of a dry etching equipment according to one embodiment of the present invention;

FIG. 6A is a view illustrating a part of a manufacturing process of a semiconductor device according to one embodiment of the present invention;

FIG. 6B is a view illustrating a part of a manufacturing process of a semiconductor device according to one embodiment of the present invention;

FIG. 6C is a view illustrating a part of a manufacturing process of a semiconductor device according to one embodiment of the present invention;

FIG. 7A is a view illustrating a part of a manufacturing process of a semiconductor device according to one embodiment of the present invention;

FIG. 7B is a view illustrating a part of a manufacturing process of a semiconductor device according to one embodiment of the present invention;

FIG. 7C is a view illustrating a part of a manufacturing process of a semiconductor device according to one embodiment of the present invention;

FIG. 8 is a graph representing time-series transition of the number of particles;

FIG. 9 is a view representing problems in a dry etching equipment;

FIG. 10A is a view conceptually illustrating a reaction model during dry etching; and

FIG. 10B is a view conceptually illustrating a reaction model during dry etching.

### DETAILED DESCRIPTION OF THE PREFERRED EMBODIMENTS

Examples are explained hereunder in reference to the drawings. Here, an identical configuration is represented by an identical sign in the drawings and detailed explanations of overlapping parts are omitted.

### Example 1

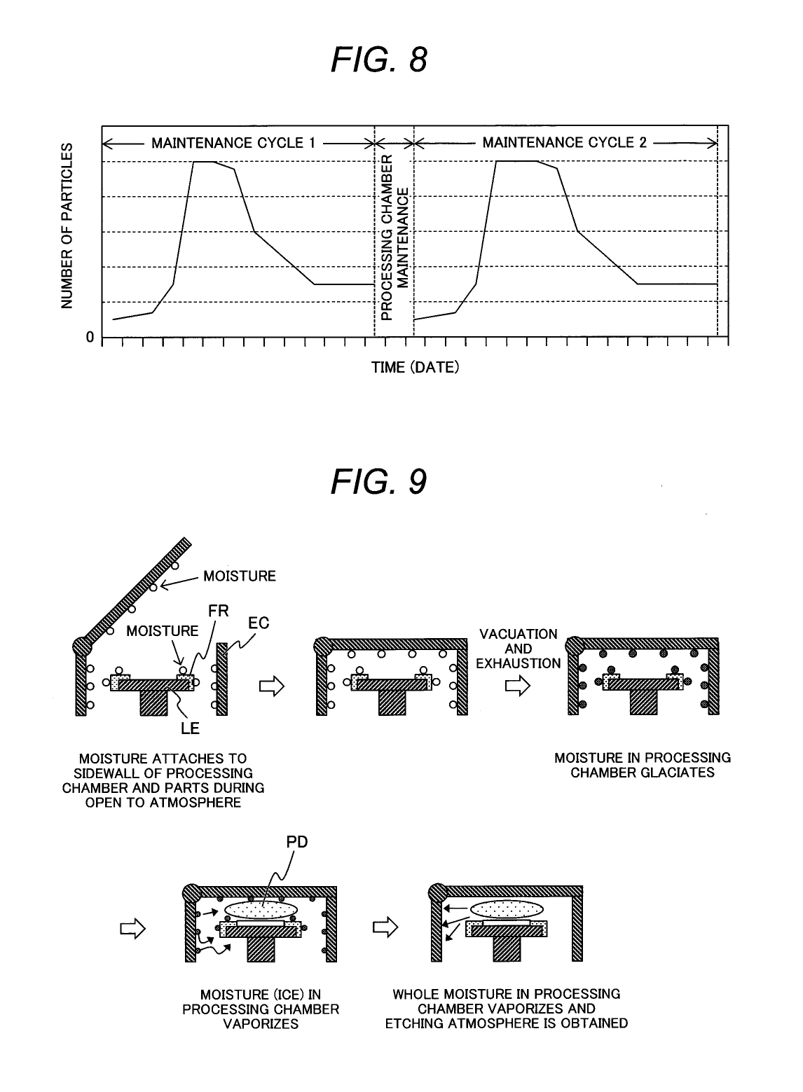

First, problems and the grounds (generating mechanisms) of a dry etching equipment are explained in reference to FIGS. 8 to 10B. FIG. 8 represents time-series transition of the number of particles generated in a dry etching equipment. The horizontal axis represents time (date) and the vertical axis represents a relative number of particles. Here, a number of particles is measured with a particle counter installed in an exhaust system (exhaust pipe) of a processing chamber in a dry etching equipment.

In FIG. 8, a time span from immediately after the maintenance of a processing chamber to the next maintenance is defined by one maintenance cycle and particle transition of two maintenance cycles (maintenance cycle 1 and maintenance cycle 2) is represented.

As represented in FIG. 8, the number of particles shifts at low levels immediately after the maintenance of a processing chamber. After the lapse of a certain period of time (here, after the lapse of about 30 hours in terms of RF cumulative applied time), however, the number of particles starts to rise rapidly and shifts at high levels for a certain period of time (between about 30 to 60 hours in terms of RF cumulative applied time). Successively, the number of particles lowers and shifts stably at low levels.

The data represented in FIG. 8 are not data obtained by directly measuring particles existing in a processing chamber but data obtained by measuring the number of particles passing through an exhaust pipe connected to a processing chamber and the transition of the number of particles in a processing chamber is considered to behave similarly to FIG. 8. When products are processed for about 30 to 60 hours in terms of RF cumulative applied time after the maintenance of a processing chamber therefore, the possibility of attaching a particle to a product and causing a defective product increases and that may possibly lead to an equipment trouble such as abnormal electric discharge.

In this context, it is conceivable to apply maintenance to a processing chamber before the number of particles increases, namely, before 30 hours lapse in terms of RF cumulative applied time, but the frequency of the maintenance increases and undesirably the operation rate of an equipment lowers extremely.

The mechanism of generating a particle is explained in reference to FIG. 9. During the maintenance of a dry etching equipment, a processing chamber is opened to the atmosphere, the inner wall of the processing chamber is wiped with methanol, a quartz and a ceramic part in the processing chamber are detached, and they are changed with new parts or replacement parts cleaned and dried beforehand. On this occasion, moisture in the atmosphere adsorbs to the inner wall of the processing chamber and the surfaces of the parts. When (the lid of) the processing chamber is closed while the moisture adsorbs to the inner wall of the processing chamber and the surfaces of the parts and the processing chamber is vacuated, the interior of the processing chamber adiabatically expands and the moisture glaciates (freezes) and stays in the processing chamber for a long period of time.

The moisture glaciated (frozen) in the processing chamber volatilizes gradually by heat inputted from a heater or plasma on the side of the equipment but, when the moisture touches a halogen gas such as a fluorine (F) gas or a chlorine (Cl) gas contained in an etching gas, an etchant is extracted by an hydrogen (H) atom in the moisture and resultantly a reaction product is generated excessively. The interior of the processing chamber is in the state of so-called “deposit rich” and a reaction product deposits excessively over the inner wall and the parts in the processing chamber.

It is estimated that, when the whole moisture in the processing chamber volatilizes as etching process advances, the balance of the reaction system in the processing chamber changes, the interior of the processing chamber is in the state of a so-called “etching atmosphere”, and a reaction product depositing in the processing chamber exfoliates and comes to be a particle.

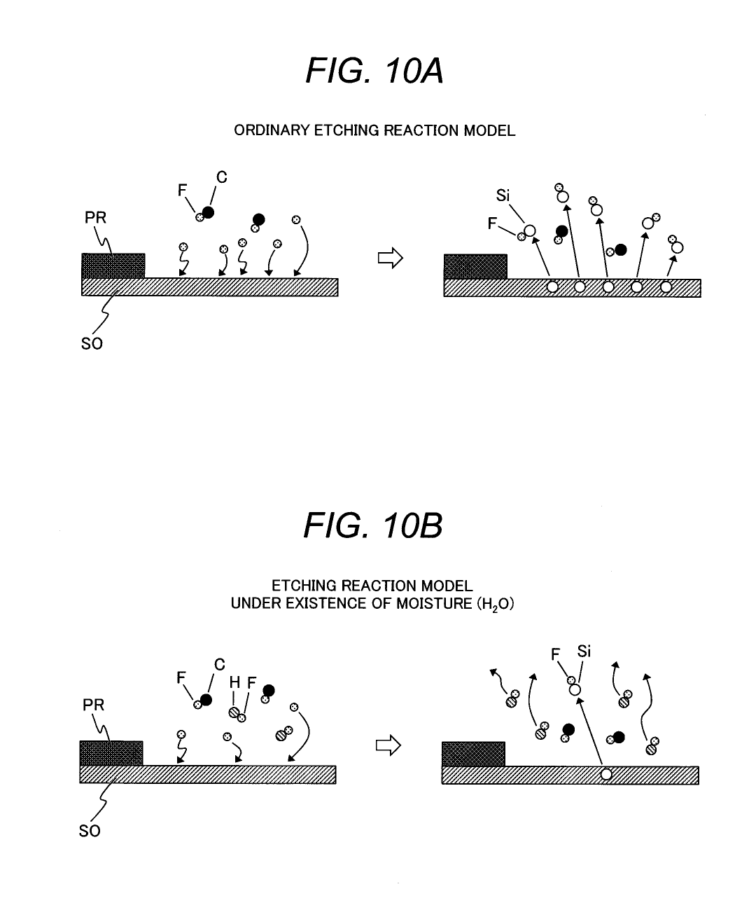

The influence of moisture in etching a silicon oxide film (SiO₂) by a fluorocarbon (CF) gas is explained in reference to FIGS. 10A and 10B. FIG. 10A represents an etching reaction model in an ordinary state of not containing moisture and FIG. 10B represents an etching reaction model in a state of containing moisture.

As represented in FIG. 10A, in the ordinary state of not containing moisture, a fluorine (F) atom that is an etchant adsorbs to the surface of a silicon oxide film SO where a photoresist PR is not formed and reacts with a silicon (Si) atom in the silicon oxide film SO, a highly-volatile silicon fluoride (SiF) is formed thereby, and the etching reaction of the silicon oxide film SO advances.

In contrast, as represented in FIG. 10B, in the state of containing moisture, a fluorine (F) atom is extracted by a hydrogen (H) atom in the moisture (H₂O) and fluorine (F) atoms over the surface of a silicon oxide film SO reduce. As a result, an F/C ratio acting as an indicator of the ratio between etching by an F radical and deposition by a C radical reduces and a “deposit rich” atmosphere is obtained.

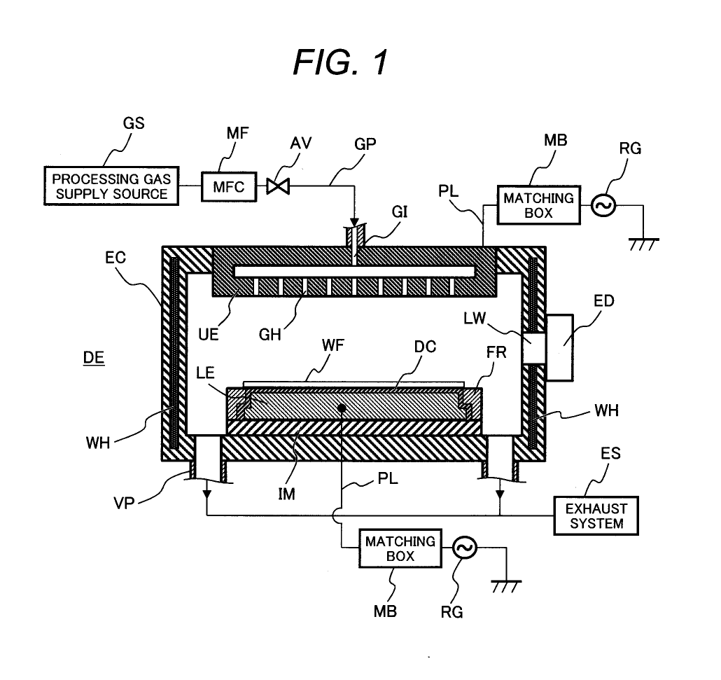

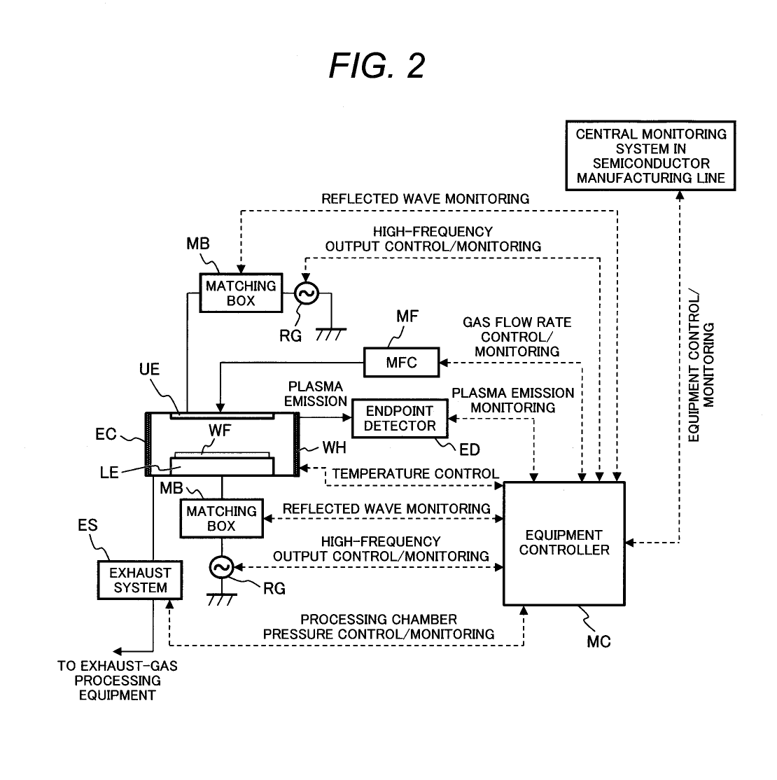

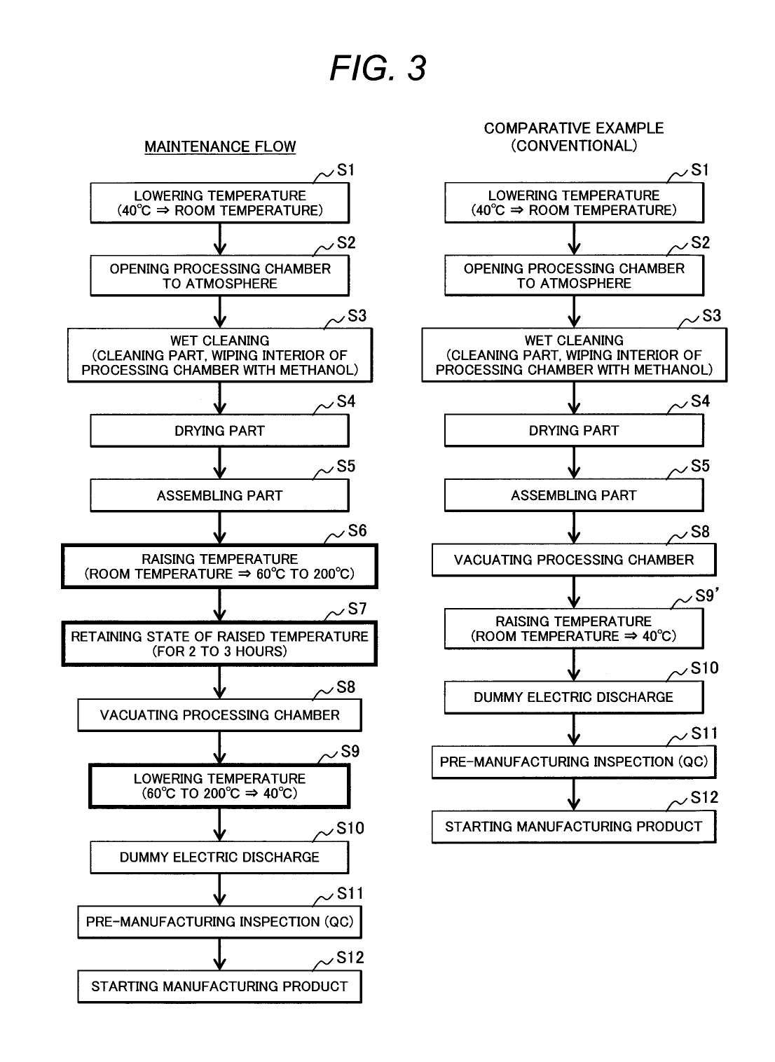

A maintenance method of a dry etching equipment according to the present example is explained hereunder in reference to FIGS. 1 to 3. FIG. 1 is a view illustrating the general outline of a dry etching equipment and a parallel plate type plasma etching equipment is illustrated as an example. FIG. 2 illustrates the outline of a control system of the dry etching equipment in FIG. 1. Further, FIG. 3 is a flowchart illustrating a maintenance method according to the present example.

In reference to FIG. 1, a dry etching equipment DE according to the present example has an upper electrode UE and a lower electrode LE, those facing each other, in a processing chamber EC. The dry etching equipment DE is structured so as to have a plurality of processing gas supply holes GH in the upper electrode UE and supply a processing gas (etching gas) introduced from a gas inlet port GI into the processing chamber EC. The upper electrode UE is a so-called shower head type upper electrode.

The processing gas (etching gas) is supplied from a processing gas supply source GS, passes through a mass flow controller (MFC) MF and an opening and closing valve AV, and is supplied to the gas inlet port GI through a processing gas supply pipe GP.

A high-frequency power source RG is electrically connected to the upper electrode UE through a power line PL via a matching box MB and a high-frequency power from the high-frequency power source RG is supplied to the upper electrode UE through the matching box MB. The high-frequency power source RG for the upper electrode UE outputs a high-frequency power of 60 MHz, for example.

Exhaust pipes VP are connected to the lower part of the processing chamber EC. The exhaust pipes VP are connected to an exhaust system ES. The exhaust system ES includes a vacuum pump such as a dry pump or a turbo-molecular pump (TMP). The interior of the processing chamber EC is vacuated by adjusting an exhaust volume with the exhaust system ES. The interior of the processing chamber EC can thereby be depressurized to a prescribed pressure.

The lower electrode LE is installed at the bottom of the processing chamber EC with an insulating member IM interposed. The lower electrode LE is formed by applying alumite coating to the surface of an aluminum (AL) substrate, for example. A focus ring FR including an insulating material such as quartz or alumina ceramics (Al₂O₃) is arranged around the lower electrode LE. The focus ring FR functions not only as a focus ring to concentrate plasma on a wafer WF over the lower electrode LE but also as a protection ring to protect the lower electrode LE against plasma.

The dry etching equipment DE is structured so as to: form a material including a dielectric material over the surface of the lower electrode LE as a dielectric coating DC by alumina thermal spraying; and attract and fix the wafer WF over the lower electrode LE by electrostatic force by applying a direct-current voltage (DC voltage) to the lower electrode LE (not illustrated in the figure). A so-called electrostatic chuck is adopted.

A high-frequency power source RG is electrically connected to the lower electrode LE through a power line PL via a matching box MB and a high-frequency power from the high-frequency power source RG is supplied to the lower electrode LE through the matching box MB similarly to the upper electrode UE. The high-frequency power source RG for the lower electrode LE outputs a high-frequency power of 2 MHz, for example.

A lighting window LW to transmit plasma emission to the exterior of the processing chamber EC while the pressure in the processing chamber EC is retained is installed at the sidewall of the processing chamber EC. An endpoint detector ED is installed at the lighting window LW. Further, a wall heater WH is embedded into the sidewall of the processing chamber EC and is structured so as to control the temperature at the surface of the inner wall of the processing chamber EC in the range of room temperature to 200° C.

The dry etching equipment DE illustrated in FIG. 1 is configured as stated above. The wafer WF is carried in the processing chamber EC and attached and fixed over the lower electrode LE and successively the interior of the processing chamber EC is vacuated to a prescribed pressure by the exhaust system ES. Successively, a processing gas (etching gas) is introduced from the processing gas supply holes GH into the processing chamber EC, plasma is generated in the processing chamber EC by applying a high-frequency power to the upper electrode UE and the lower electrode LE, respectively, and dry etching processing (plasma processing) is applied to the wafer WF attached and fixed over the lower electrode LE.

FIG. 2 is a block diagram schematically illustrating a control system to control the dry etching equipment DE illustrated in FIG. 1. As illustrated in FIG. 2, a equipment controller MC: is connected to an exhaust system ES, a mass flow controller MF, a high-frequency power source RG for an upper electrode UE, a matching box MB for the upper electrode UE, a high-frequency power source RG for a lower electrode LE, a matching box MB for the lower electrode LE, and an endpoint detector ED; and controls and monitors the respective equipment units. Further, the equipment controller MC is connected also to a wall heater WH embedded into the sidewall of a processing chamber EC and controls the temperature of the inner wall of the processing chamber EC.

The equipment controller MC has a memory to memorize processing conditions (process recipes) and controls the respective equipment units in accordance with the processing conditions (process recipes) memorized (set) in the memory. Further, allowable ranges of the processing conditions (process recipes) are memorized (set) in the memory beforehand, abnormality is judged to occur in the dry etching equipment DE when an observed value (monitored value) of one of the equipment units exceeds the allowable range, and an alarm is sent to the exterior directly from the dry etching equipment DE or through a centralized monitoring system in a semiconductor manufacturing line in which the dry etching equipment DE is installed.

FIG. 3 is a flowchart representing a maintenance method according to the present example. A conventional maintenance method is represented on the right side in FIG. 3 for comparison. First, the conventional maintenance method of a dry etching equipment is explained in reference to the comparative example (conventional) of FIG. 3.

Generally in a dry etching equipment, the sidewall of a processing chamber is heated to about 40° C. in order to restrain a reaction product from depositing on the inner wall of the processing chamber. During maintenance therefore, firstly the temperature of the sidewall of the processing chamber is lowered (cooled) from 40° C. to room temperature (Step S1).

Successively, the processing chamber retained in a vacuum is purged with a nitrogen (N₂) gas and the processing chamber is opened to the atmosphere (Step S2).

Successively, a reaction product depositing on the inner wall of the processing chamber and a part in the processing chamber is removed by wet cleaning (washing) (Step S3). On this occasion, since the inner wall of the processing chamber cannot be detached easily, the reaction product over the surface is wiped off with a non-woven fabric into which a solvent such as methanol seeps for example. Further, a part such as a quartz or alumina ceramics in the processing chamber is detached once from the processing chamber, cleaned with a solvent such as methanol, and successively dried sufficiently in a clean environment such as in a dry draft (Step S4).

Successively, the dried part is assembled into the processing chamber (Step S5), (the lid of) the processing chamber is closed, and subsequently the processing chamber is vacuated (Step S8).

Successively, a heater power source to restrain a reaction product from depositing over the inner wall of the processing chamber is turned on and the temperature is raised from room temperature to 40° C. (Step S9′).

Successively, dummy electric discharge for preconditioning electric discharge is applied if necessary (Step S10) and, through pre-manufacturing QC such as particle inspection and etching characteristic inspection (Step S11), the manufacturing of a product starts (Step S12).

The flow of the maintenance method according to the present example is identical to the flow of the conventional maintenance method from Step S1 to Step S5 as represented on the left side in FIG. 3. The maintenance method according to the present example, however, is different from the conventional maintenance method on the point of including the process of raising the temperature of (heating) the processing chamber (Step S6) and the process of retaining the heated state for a certain period of time (Step S7) after a part is assembled into the processing chamber at Step S5 before the processing chamber is vacuated at Step S8.

At Step S6, in the state of opening (the lid of) the processing chamber to the atmosphere, the temperature of the inner wall of the processing chamber is raised (heated) from room temperature to the range of 60° C. to 200° C. with a wall heater WH embedded into the sidewall of the processing chamber. The moisture adsorbing to the inner wall of the processing chamber and the surface of a part in the processing chamber is removed sufficiently by retaining the state of raising temperature (being heated) for a certain period of time (2 to 3 hours here).

Here, although the time required for removing moisture reduces as the raised temperature (temperature after heating) increases, the degree is determined by the capacity of a wall heater WH. Since the target of the removal is moisture, a preferable temperature is desirably set at a temperature of not less than the boiling point of water (100° C.)

Further, since the likelihood of the vaporization of water varies also in accordance with the shapes of an inner wall and a part in a processing chamber and a surface state, as the time for retaining the state of raising temperature (being heated), a retaining time allowing moisture to be sufficiently vaporized is set desirably in accordance with the machine type of a target dry etching equipment and the surface condition (roughed surface condition caused by wear) of a part and the like.

After the moisture in the processing chamber is vaporized sufficiently at Steps S6 and S7, the processing chamber is vacuated (Step S8).

Subsequently, the temperature of the processing chamber (60° C. to 200° C.) raised (heated) at Steps S6 and S7 is lowered (cooled) to a processing temperature (40° C.) (Step S9).

Successively, in the same manner as the conventional maintenance method, dummy electric discharge for preconditioning electric discharge is applied if necessary (Step S10) and, through pre-manufacturing QC such as particle inspection and etching characteristic inspection (Step S11), the manufacturing of a product starts (Step S12).

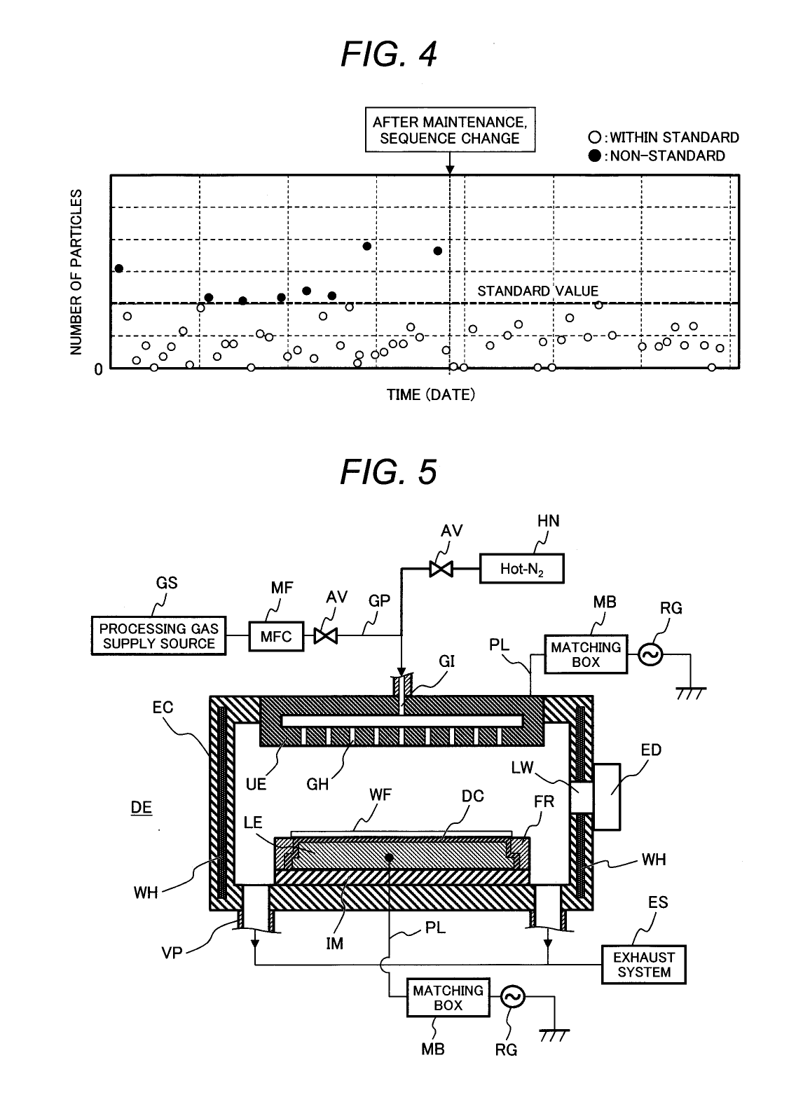

An example of the effects in the present example is explained in reference to FIG. 4. FIG. 4 represents time-series transition of the number of particles between before and after sequence change after the maintenance explained above. The horizontal axis represents time (date) and the vertical axis represents a relative value of the number of particles. As it is obvious from FIG. 4, whereas the number of particles is higher than a standard value, namely the state of frequent generation of particles disperses, in the conventional maintenance method, the number of particles remains not more than a standard value stably after the maintenance method according to the present example is applied.

As explained in the flowchart of FIG. 3, since moisture in the processing chamber is vaporizes sufficiently by raising the temperature of (heating) the processing chamber before the processing chamber is vacuated and the moisture does not glaciate (freeze) in the processing chamber when the processing chamber is vacuated, it is possible to restrain the influence of the moisture during the succeeding process to the greatest possible extent.

### Example 2

A maintenance method of a dry etching equipment according to Example 2 is explained in reference to FIG. 5. The main configuration of a dry etching equipment DE illustrated in FIG. 5 is nearly identical to the dry etching equipment in FIG. 1 and hence detailed explanations are omitted. The dry etching equipment DE in FIG. 5 is different from the dry etching equipment in FIG. 1 on the point that a hot nitrogen (N₂) supply source HN is connected to a processing gas supply pipe GP to supply an etching gas to a processing chamber with an opening and closing valve AV interposed.

In the present example, by connecting the hot nitrogen (N₂) supply source HN to the processing gas supply pipe GP, a heated nitrogen (N₂) gas can be supplied into the processing chamber in the state of closing (the lid of) the processing chamber between Step S7 and Step S8 before the processing chamber is vacuated, for example, in the flowchart of FIG. 3. The temperature of the supplied nitrogen (N₂) gas is set at about 60° C. to 200° C. similarly to a wall heater WH. Further, the nitrogen (N₂) gas supplied into the processing chamber is exhausted through an exhaust line in the processing chamber. It is thereby possible to remove moisture more effectively in the processing chamber before the processing chamber is vacuated.

Here, the supply and exhaustion of a heated nitrogen (N₂) gas may be either applied simultaneously and continuously or repeated alternatively, namely subjected to cycle purge.

Further, although raising temperature (heating) with a wall heater WH and raising temperature (heating) with a hot nitrogen (N₂) are used in combination in FIG. 5, it is also possible to use only the raising temperature (heating) with a hot nitrogen (N₂) without using a wall heater WH. On this occasion, the supply and exhaustion of the hot nitrogen (N₂) into and from the processing chamber are applied simultaneously and continuously or as cycle purge in the state of closing (the lid of) the processing chamber after a part is assembled (Step S5) before the processing chamber is vacuated (Step S8) in the flowchart of FIG. 3.

### Example 3

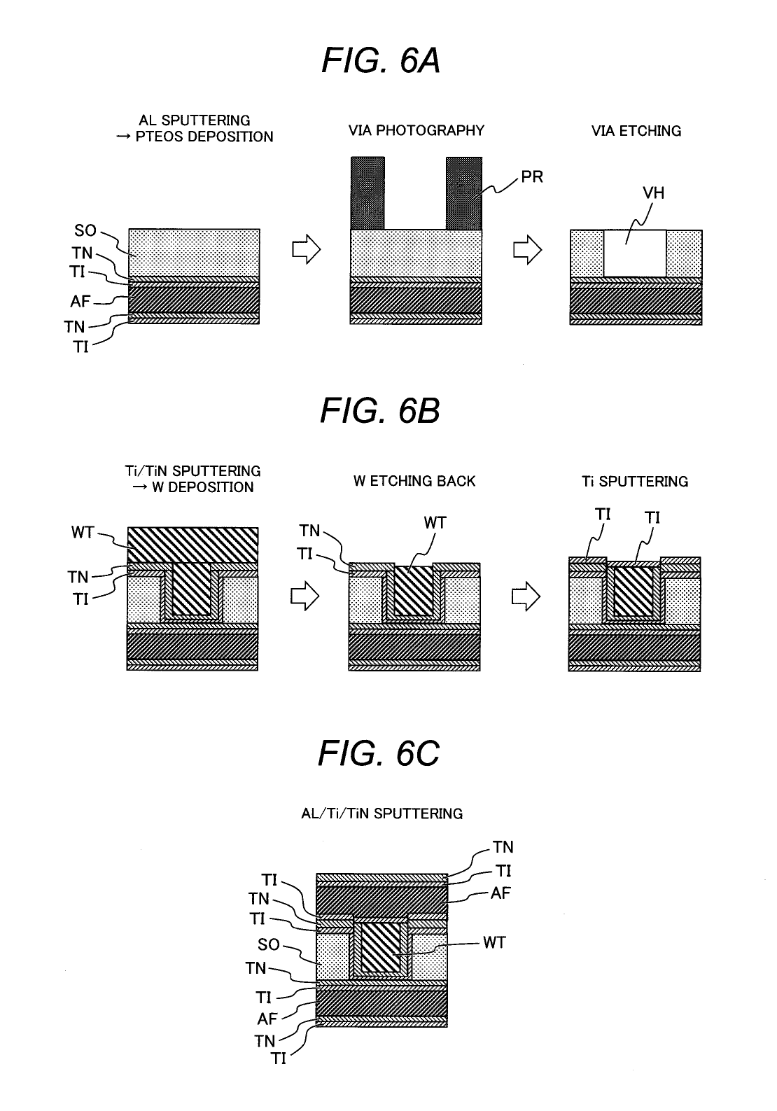

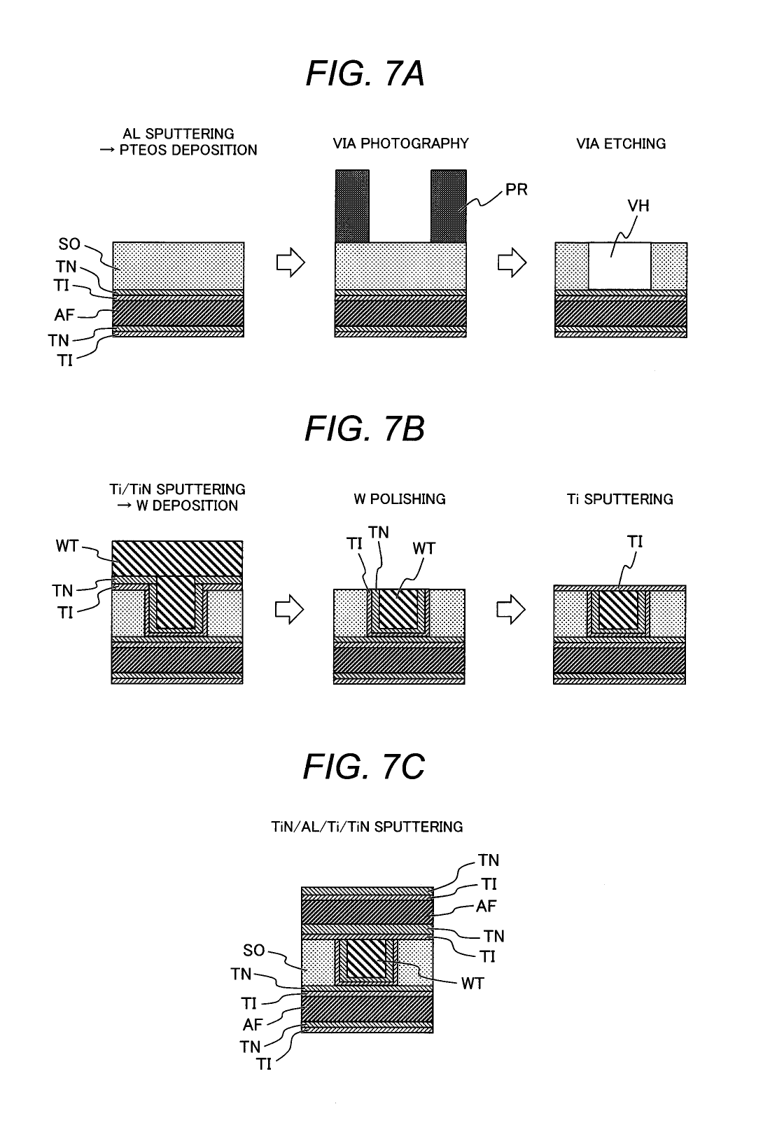

A manufacturing method of a semiconductor device to which a maintenance method explained in Example 1 or 2 is applied is explained in reference to FIGS. 6A to 7C. FIGS. 6A to 6C illustrate a process flow for forming a tungsten (W) via by an etch-back method of dry etching. Further, FIGS. 7A to 7C illustrate a process flow for forming a tungsten (W) via by CMP (Chemical Mechanical Polishing).

First, processes from an AL sputtering process to a via etching process are explained in reference to FIG. 6A. A laminated film including a titanium (Ti) film TI of a lower layer, a titanium nitride (TiN) film TN of the lower layer, an aluminum (AL) film AF, a titanium (Ti) film TI of an upper layer, and a titanium nitride (TiN) film TN of the upper layer is formed in sequence from the lower layer over the principal surface of a semiconductor substrate (not shown in the figure) with a sputtering equipment. The thicknesses of the films are about 8 to 12 nm in the case of the titanium (Ti) film TI of the lower layer, about 70 to 80 nm in the case of the titanium nitride (TiN) film TN of the lower layer, about 350 to 450 nm in the case of the aluminum (AL) film AF, about 8 to 12 nm in the case of the titanium (Ti) film TI of the upper layer, and about 70 to 80 nm in the case of the titanium nitride (TiN) film TN of the upper layer. Here, the thicknesses are only the examples and are not limited to the examples.

Subsequently, a silicon oxide film (SiO₂ film) SO including a PTEOS (Plasma Tetra Ethyl Ortho Silicate) film for example is formed over the titanium nitride (TiN) film TN of the upper layer with a CVD (Chemical Vapor Deposition) equipment. The thickness of the PTEOS film is about 800 to 1,000 nm.

Successively, a photoresist film PR is applied over the silicon oxide film SO with a coater and a via hole pattern is formed over the photoresist film PR by lithography. Subsequently, a dry etching process is applied to the silicon oxide film SO with the via hole pattern used as a mask and a via hole VH is formed in the silicon oxide film SO.

A dry etching equipment subjected to maintenance by a maintenance method explained in Example 1 or 2 is used for the dry etching. More specifically, via etching is applied with a dry etching equipment subjected to temperature rise (heating) with a wall heater WH or by the supply of hot nitrogen (N₂) before the processing chamber is vacuated after a processing chamber is opened to the atmosphere and a reaction product is removed and a part is changed in the processing chamber.

As explained in Examples 1 and 2, by raising the temperature in (heating) a processing chamber before the processing chamber is vacuated, it is possible to: sufficiently vaporize the moisture adsorbing to the inner wall and the surface of a part in the processing chamber; and restrain a particle from being generated in the processing chamber as illustrated in FIG. 4. As a result, it is possible to restrain etching failure in a via etching process and improve a manufacturing yield. Further, it is also possible to restrain the opening failure of a via hole VH and the like in a via etching process and improve the reliability of a semiconductor device.

Here, as explained in FIG. 10B, when moisture exists in a processing chamber, since the reaction model of etching is in the state of “deposition rich”, a reaction product attaches to the sidewall of a via hole VH and a targeted hole diameter is difficult to be processed in a via etching process. Then by using a dry etching equipment subjected to the maintenance explained in Example 1 or 2 in a via etching process, it is possible to restrain the influence of moisture during via etching and apply via etching of a higher degree of accuracy.

Subsequently, processes from a Ti/TiN sputtering process to a Ti sputtering process are explained in reference to FIG. 6B. A titanium (Ti) film TI and a titanium nitride (TiN) film TN are formed so as to cover the inside of the via hole VH and the surface of the silicon oxide film SO with a sputtering equipment. The thicknesses of the films are about 8 to 12 nm in the case of the titanium (Ti) film TI and about 70 to 80 nm in the case of the titanium nitride (TiN) film TN. Subsequently, a tungsten (W) film WT is formed over the titanium nitride (TiN) film TN so as to be embedded into the via hole VH with a CVD equipment. The thickness of the tungsten (W) film WT is about 450 to 550 nm.

Subsequently, an excessive tungsten (W) film WT over the titanium nitride (TiN) film TN is etched back and removed with the tungsten (W) film WT in the via hole VH left with a dry etching equipment. On this occasion, a dent called a recess is formed over the surface of the tungsten (W) film WT in the via hole VH. Here, as the dry etching equipment used in the etch-back process too, a dry etching equipment by a maintenance method explained in Example 1 or 2 may be used. By restraining a particle from being generated in the etch-back process, it is possible to restrict product failure and improve a manufacturing yield.

Subsequently, a titanium (Ti) film TI is formed over the surface of the titanium nitride (TiN) film TN and the tungsten (W) film WT in the via hole VH with a sputtering equipment. The thickness of the titanium (Ti) film TI is about 8 to 12 nm.

AL/Ti/TiN sputtering processes are explained hereunder in reference to FIG. 6C. An aluminum (AL) film AF is formed with a CVD equipment. The thickness of the aluminum (AL) film AF is about 350 to 450 nm. Subsequently, a titanium (Ti) film TI and a titanium nitride (TiN) film TN are formed in sequence from the lower layer over the aluminum (AL) film AF with a sputtering equipment. The thicknesses of the films are about 8 to 12 nm in the case of the titanium (Ti) film TI and about 80 to 120 nm in the case of the titanium nitride (TiN) film TN.

A via structure illustrated in FIG. 6C is formed through the processes explained above. According to the manufacturing method of a semiconductor device illustrated in FIGS. 6A to 6C, a dry etching equipment by a maintenance method explained in Example 1 or 2 is used for via hole etching and thus it is possible to restrain a particle from being generated during via etching, restrain a via hole diameter from varying, hence restrain a high-resistance via from being formed, and manufacture a semiconductor device of a high degree of reliability.

A manufacturing method using a W-CMP equipment is explained hereunder in reference to FIGS. 7A to 7C. The major difference between the manufacturing method illustrated in FIGS. 6A to 6C and the manufacturing method illustrated in FIGS. 7A to 7C is whether an excessive tungsten (W) film WT outside a via hole VH is removed by etch-back method or by W polishing and hence explanations are made while common parts are omitted. Further, the thicknesses of various kinds of formed films vary in accordance with the process generations of products adopting respective manufacturing methods, but are unrelated to the tenor of the present application, and hence are omitted in detailed explanations referring to FIGS. 7A to 7C.

FIG. 7A illustrates processes from an AL sputtering process to a via etching process similarly to FIG. 6A. The processes are basically identical to FIG. 6A except for the difference of the thicknesses of the various films. To via hole etching applied from a via photographing process to a via etching process in FIG. 7A therefore, a dry etching equipment allowing moisture adsorbing to the inner wall of a processing chamber and the surface of a part to be vaporized sufficiently by raising the temperature (heating the interior) of the processing chamber before the processing chamber is vacuated is applied as explained in Examples 1 and 2.

Successively, as illustrated in FIG. 7B, a titanium (Ti) film TI and a titanium nitride (TiN) film TN are formed so as to cover the interior of a via hole VH and the surface of a silicon oxide film SO with a sputtering equipment and subsequently a tungsten (W) film WT is formed over the titanium nitride (TiN) film TN so as to be embedded into the via hole VH with a CVD equipment.

Subsequently, an excessive tungsten (W) film WT outside the via hole VH is removed by CMP with a W-CMP equipment. Here, the titanium nitride (TiN) film TN over the silicon oxide film SO functions as a stopper film during CMP, but is damaged by the CMP, and hence is removed by wet etching or the like after the CMP.

Successively, a titanium (Ti) film TI is formed over the silicon oxide film SO, the titanium (Ti) film TI, and the titanium nitride (TiN) film TN with a sputtering equipment.

Subsequently, after a titanium nitride (TiN) film is formed over the titanium (Ti) film TI with a sputtering equipment likewise, an aluminum (AL) film AF is formed with a CVD equipment, finally a titanium (Ti) film TI and a titanium nitride (TiN) film TN are formed over the aluminum (AL) film AF with a sputtering equipment, and thus a via structure illustrated in FIG. 7C is formed. According to the manufacturing method of a semiconductor device illustrated in FIGS. 7A to 7C, a dry etching equipment by a maintenance method explained in Example 1 or 2 is used for via hole etching and it is possible to restrain a particle from being generated during via etching, restrain a via hole diameter from varying, hence restrain a high-resistance via from being formed, and manufacture a semiconductor device of a high degree of reliability.

Here, the metal wiring of the laminated structure explained in FIGS. 6A to 7C is based on a five-layered structure including a titanium (Ti) film, a titanium nitride (TiN) film, an aluminum (AL) film, a titanium (Ti) film, and a titanium nitride (TiN) film in sequence from the lower layer but is not limited to the structure and the titanium (Ti) films of the upper and lower layers may be excluded, for example. For example, a three-layered structure including a titanium nitride (TiN) film, an aluminum (AL) film, and a titanium nitride (TiN) film may also be acceptable.

Further, although the explanations in the present example are made on the basis of the example of using via hole etching when a via hole (contact hole) is formed in a silicon oxide film, the present invention is not limited to the example and is effective also in the case of forming a gate electrode by applying a maintenance method of Example 1 or 2 to a dry etching equipment of a polysilicon (poly-Si) film, for example.

Likewise, the present invention is effective also in the case of forming an aluminum wire by applying a maintenance method of Example 1 or 2 to a dry etching equipment of an aluminum (Al) film.

Although the invention established by the present inventors has heretofore been explained concretely on the basis of the embodiments, the present invention is not limited to the embodiments and it goes without saying that the present invention can be modified variously within the range not departing from the tenor of the present invention.

Here, an example of the features of the present application is a maintenance method of a dry etching equipment, the maintenance method including the processes of: opening a processing chamber of the dry etching equipment to the atmosphere; removing a reaction product attaching to the inner wall of the processing chamber and a part in the processing chamber; closing the processing chamber; successively exhausting a nitrogen gas from an exhaust port of the processing chamber while the heated nitrogen gas is introduced from a gas inlet of the processing chamber; retaining the introduction and exhaustion of the heated nitrogen gas for a certain period of time; stopping the introduction of the nitrogen gas; and successively vacuating the processing chamber.

Further, another example of the features is a maintenance method of a dry etching equipment, the maintenance method including the processes of: vacuating a processing chamber; and successively cooling the interior of the processing chamber.

Furthermore, still another example of the features is a maintenance method of a dry etching equipment, the maintenance method including the process of removing a reaction product attaching to a part in a processing chamber by replacing the part in the processing chamber with a new part or a spare part cleaned and dried beforehand.

### REFERENCE SIGNS LIST

PR Photoresist
SO Silicon oxide film
DE Dry etching equipment
EC Processing chamber
UE Upper electrode
GS Processing gas supply source
MF Mass flow controller (MFC)
AV Opening and closing valve
GP Processing gas supply pipe
GI Gas inlet port
GH Processing gas supply hole
LE Lower electrode
FR Focus ring
DC Dielectric coating
WF Wafer
IM Insulating member
VP Exhaust pipe
ES Exhaust system
RG High-frequency power source
MB Matching box
PL Power line
LW Lighting window
ED Endpoint detector
WH Wall heater
MC Equipment controller
HN Hot nitrogen (N₂) supply source
PD Plasma (electric discharge)
TI Titanium (Ti) film
TN Titanium nitride (TiN) film
PR Photoresist film
WT Tungsten (W) film
AF Aluminum (AL) film
VH Via hole

What is claimed is:

1. A manufacturing method of a semiconductor device, the manufacturing method comprising the processes of:
(a) while a processing chamber is opened to the atmosphere, heating the interior of the processing chamber and retaining the heated state for a certain period of time;
(b) after the process (a), closing the processing chamber and vacuating the processing chamber;
(c) after the process (b), carrying a semiconductor wafer over the principal surface of which a film to be etched is formed in the processing chamber; and
(d) after the process (c), introducing an etching gas into the processing chamber, generating plasma in the processing chamber by exiting molecules of the etching gas, and applying a plasma etching process to the film to be etched.

2. A manufacturing method of a semiconductor device according to claim 1, the manufacturing method comprising the process of (e) cooling the interior of the processing chamber between the processes (b) and (c).

3. A manufacturing method of a semiconductor device according to claim 1, wherein at least the inner wall of the processing chamber is heated in the process (a).

4. A manufacturing method of a semiconductor device according to claim 3, wherein the inner wall of the processing chamber is heated with a heater installed at the sidewall of the processing chamber.

5. A manufacturing method of a semiconductor device, the manufacturing method comprising the processes of:
(a) after a processing chamber is opened to the atmosphere, closing the processing chamber;
(b) after the process (a), while a heated nitrogen gas is introduced from a gas inlet port of the processing chamber, exhausting the nitrogen gas from an exhaust port of the processing chamber and retaining the introduction and exhaustion of the heated nitrogen gas for a certain period of time;
(c) after the process (b), vacuating the processing chamber;
(d) after the process (c), carrying a semiconductor wafer over the principal surface of which a film to be etched is formed in the processing chamber; and
(e) after the process (d), introducing an etching gas into the processing chamber, generating plasma in the processing chamber by exiting molecules of the etching gas, and applying a plasma etching process to the film to be etched.

6. A manufacturing method of a semiconductor device according to claim 5, the manufacturing method comprising the process of (f) cooling the interior of the processing chamber between the processes (c) and (d).

7. A maintenance method of a dry etching equipment, the maintenance method comprising the processes of:
opening a processing chamber of the dry etching equipment to the atmosphere;
removing a reaction product attaching to an inner wall of the processing chamber and a part in the processing chamber;
while the processing chamber is opened to the atmosphere, heating the interior of the processing chamber and retaining the heated state for a certain period of time; and
closing the processing chamber and successively vacuating the processing chamber.

8. A maintenance method of a dry etching equipment according to claim 7, wherein the interior of the processing chamber is cooled after the processing chamber is vacuated.

9. A maintenance method of a dry etching equipment according to claim 7, wherein at least the inner wall of the processing chamber is heated.

10. A maintenance method of a dry etching equipment according to claim 9, wherein the inner wall of the processing chamber is heated with a heater installed at the sidewall of the processing chamber.

11. A maintenance method of a dry etching equipment according to claim 7, wherein a reaction product attaching to a part in the processing chamber is removed by replacing the part in the processing chamber with a new part or a spare part cleaned and dried beforehand.
